(19) United States
(12) Patent Application Publication
(10) Pub. No.: US 2010/0163096 A1
(43) Pub. Date: Jul. 1, 2010

(54) Economic solar electricity panel system

(75) Inventors: Edward Palen, Sausallto, CA (US); Michael Lee Fulton, Thousand Oak, CA (US); Michael Phillip Newell, Santa Rosa, CA (US); Richard Brown, Petaluma, CA (US)

Correspondence Address: JEFFER, MANGELS, BUTLER & MARMARO, LLP, 1900 AVENUE OF THE STARS, 7TH FLOOR, LOS ANGELES, CA, 90067, US

(73) Assignee: COOL PLANETSOLAR LLC

(21) Appl. No.: 12/317,821

(22) Filed: Dec. 29, 2008

(51) Int. Cl. H01L 31/052; H01L 31/00; H01L 31/042

(52) U.S. Cl. 136/246; 136/259; 136/244

(57) ABSTRACT

Economical sunlight collection panels are constructed to minimize the cost to generate electricity from solar radiation. The panels use a plurality of fixed plastic linear lenses to collect sunlight over a wide arc of solar movement and concentrate the collected light onto a plurality of relatively expensive narrow strips of photovoltaic material. The photovoltaic strips are moved in an arculate path and maintained parallel to the lenses so that the lines of light concentrated by the lens remain on the strips and produce electricity over a wide portion of the sun's path across the sky, even though the area of the photovoltaic strips is minimized for economy.

### BACKGROUND OF THE INVENTION

1. Technical Field of the Invention

The present invention relates to an economical sunlight concentration apparatus for gathering sunlight and concentrating it to shine on a plurality of narrow strips of photovoltaic material.

2. Related Art

In recent years, various types of sunlight collection apparatuses for gathering sunlight, i.e. natural light, and guiding the light to shine on photovoltaic material have been proposed. Some involve fiber optics, electro-optic lens, or large motion bases. For any of such systems to be commercially viable, they must maximize the usage of available space and minimize the cost of generated electricity by substituting economical apparatus for expensive apparatus and by maximizing the usage of available space. In most cases, photovoltaic material is the most expensive component of solar electric energy systems so its usage must be minimized. Also expensive tracking systems are not viable, and glass, or sophisticated highly polished plastic lenses and mirrors are too expensive, heavy, or both. Also the solar systems, when installed on buildings, must be installable on roofs without requiring expensive modifications to the property. Generally this means minimal building intrusion and minimal roof reinforcement. Preferably, a solar system installed on a roof should be light enough that no building reinforcement is required and the only intrusion is for an electrical cable.

### SUMMARY OF THE INVENTION

The present invention includes solar panels, each having an array of linear plastic lens fixed in an East-West orientation, parallel to the horizon and facing the sun. Generally, the lens are positioned so they are perpendicular to the sun's rays at mid-morning and mid-afternoon on the first day of spring, or at its position for maximum daily received sun power. The latitude angle may be manually adjustable for large commercial systems when such is economic by having manually movable fixed positions which are adjusted for the summer and winter seasons. An East-West tracker for the panels may be employed for increased received solar radiance for tracker systems that have economical benefit. Since the motion of the sun is predictable, such motion may be controlled by a computer with a clock.

The lens array is aligned perpendicular to the horizon, such results in a larger acceptance angle requirement so usually, the lens are aligned parallel to the horizon to collect sunlight over a wide arc of solar movement and to concentrate the collected light onto relatively expensive narrow strips of photovoltaic material positioned beneath and parallel thereto. A concentration ratio of 20 to 1 for sunlight onto the photovoltaic strips is typical, the ratio required being a function of photovoltaic material cost to lens cost with the high ratios being limited by the heat buildup in the photovoltaic material, aberrations at extreme off axis collection, mechanical alignment tolerance costs, and panel profile height limitations of weight, cost and wind resistance. Generally 5 to 1 concentration is the minimal concentration ratio for the present economical system invention.

The plurality of photovoltaic strips are fixed to a heat conductive panel which is moved in an atculate path and maintained parallel to the lenses so that the lines of light concentrated by the lenses remain on the photovoltaic strips to produce electricity over a large portion of the sun's path across the sky, 60° or more. The area of the photovoltaic strips is minimized for economy. Usually the sun's energy is diminished by the atmosphere and angle when positioned beyond 60° from high noon and becomes uneconomic to collect.

The back side of the heat conductive panel is a convection radiator of solar energy accumulated as thermal energy in the panel and may be is finned to reject heat so that the temperature of the photovoltaic strips does not rise to an extent that the efficiency of the photovoltaic is significantly reduced. Although not as heat conductive as copper, the silicon of the photovoltaic material is effective in spreading the heat. Therefore, the line of light can be allowed to focus relatively sharply on the photovoltaic strip without damage thereto, or loss of system photovoltaic conversion efficiency. Normally the heat concentration from a sharp focus is not a problem because the economic lenses used do not have to have the optical quality required to produce a sharp focus.

Since the sun moves across the sky relatively slowly each day, the controller to move the heat conductive panel may be small, light weight, inexpensive and reliable. Typically, a small dither built into the controller and a monitor of electrical output, or a computer with a clock can be used to keep the heat conductive panel in the proper position throughout the day. Being small and driving a light weight panel, the controller can be solar powered from a small fixed solar cell on the solar panel, sized to produce enough electrical power to operate the controller when the sun is beyond the 30° from mid-afternoon, or a rechargeable battery charged during the preceding day. Since the morning “start” and afternoon “stop” positions of the heat conductive panel are the same, the controller is required to move the heat conductive panel only when sufficient solar should exist. By mounting the heat conductive panel by at least three pins in at least three mated arculate grooves, the heat conductive panel can be maintained parallel to the lens and in proper position so that the plurality of lines of solar energy produced by the lenses remain on the plurality of photovoltaic strips. The controller may be a single chip computer with a look up table memory or an equation of the sun's movement for the installation position for time and position synchronism.

The lenses are made from acrylic plastic that is extruded, or extruded with calendar rolls, embossing drums or other shape controlling processes and then cut to the proper length. Optically, the lenses in the lens array meet the system optical tolerance requirements, such as focal length and pitch at an economic system cost. Other lens array fabrication methods such as casting, injection molding, and polishing are generally too expensive for consideration. The arculate path of the heat conductive base allows some compromise in line width about the theoretical focus depth so that solar energy is collected most economically. The heat conductive panel is environmentally sealed within the case of the solar panel by a flexible bladder to prevent contamination by insects, dust, or moisture in the volume between the array of lenses and the heat conductive base. The flexible bladder may be molded with accordion folds to reduce the stresses therein and provide a reasonable lifetime even though the bladder may be subject to damage due to temperature and wind thrown debris. Therefore, removable mounting for the bladder is preferred so it can easily be replaced.

It is therefore a principle object of the present invention to provide efficient stationary solar panels at an economic cost.

Another object is to concentrate solar energy to minimize the amount of photovoltaic material required to convert the solar energy falling on a given area into electricity.

Another object is to minimize the space required, especially for solar module depth profile, and weight for a solar array.

Another object is to provide solar panels that maximize the use of available roof space for the production of electricity while minimizing the need to modify the roof of a commercial building for “after market” installation.

Another object is to provide solar generated electricity in areas of direct sunlight.

These and other objects and advantages of the present invention will become apparent to those skilled in the art after considering the following detailed specification along with the accompanying drawings wherein:

### BRIEF DESCRIPTION OF THE DRAWINGS

FIG. 1A is a illustration showing how the present invention is orientated on the first day of spring at mid-morning;

FIG. 1B is a diagrammatic view of the invention of FIG. 1;

FIG. 2 is an enlarged detail view of FIG. 1A;

FIG. 3 is an enlarged detail view of FIG. 2 showing how the solar panels of an array of the present invention are spaced on a roof;

FIG. 4 is a top view of the array of FIG. 3;

FIG. 5 is a side view of one possible hinged adjustable mounting of the solar panel to allow for seasonal variation of the sun's arculate path through the sky;

FIG. 6A is a perspective cutaway view of a panel constructed in accordance with the present invention;

FIG. 6B is a cross-section view of the frame of the panel of FIG.6A;

FIG. 6C is a bottom view of the frame of the panel of FIGS. 6A and 6B showing how the environmentally protective bellows is connected thereto;

FIGS. 7A, 7B, and 7C are direct sunlight ray traces of the lens of the present invention at 30°, 15°, and 0° angles relative to the lens axes;

FIG. 8 is a view showing the invention's toleration to inaccuracies of lens focal depth and photovoltaic strip width;

FIG. 9 is a graph of an upper line of focus, a mid-point line of focus, and a lower line of focus for the lens over a 60° sunlight illumination angles around the lens axis;

FIG. 10 is a highly enlarged ray trace; showing lens optical aberrations at a 30° sun angle at maximized lens aperture and minimized system cost;

FIG. 11 is a perspective view showing a photovoltaic cell assembly to a heat spreader bus bar;

FIG. 12 is a perspective view showing a photovoltaic cell assembly for connection to a modified heat spreader;

FIG. 13 is a perspective view showing a photovoltaic cell assembly for connection to another modified heat spreader;

FIG. 14 is a cross-sectional view of a photovoltaic strip with an environmental shield comprising a transparent plastic sheet and index matching transparent glue; and

FIG. 15 is a cross-sectional view of the photovoltaic strip of FIG. 14 with an inverted lens.

### DETAILED DESCRIPTION OF THE SHOWN EMBODIMENTS

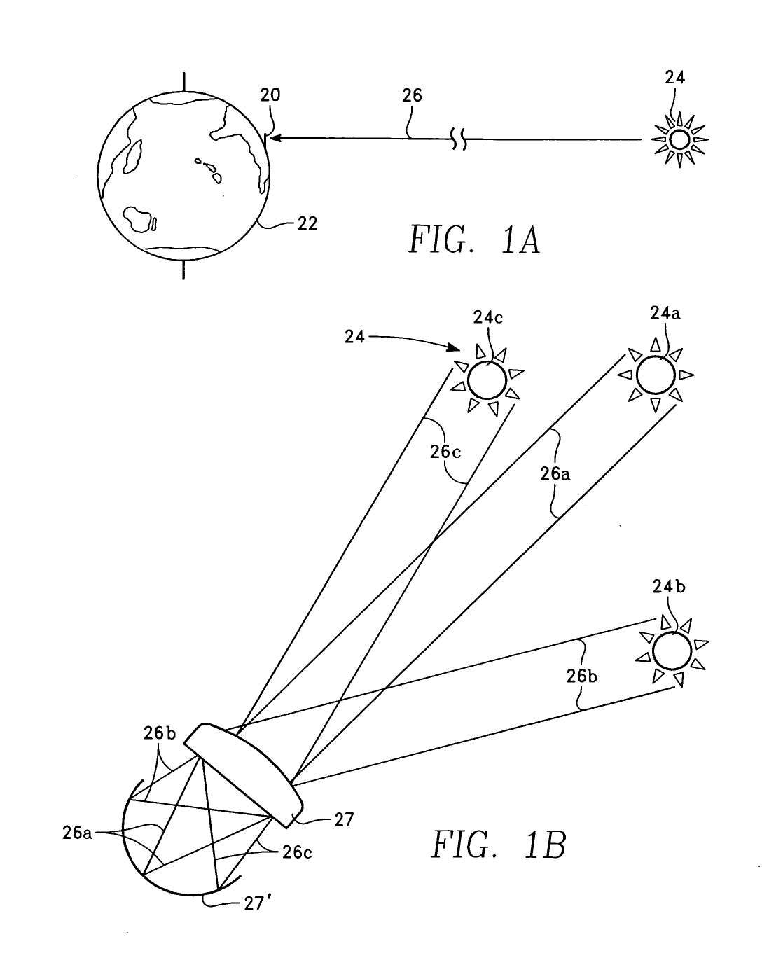

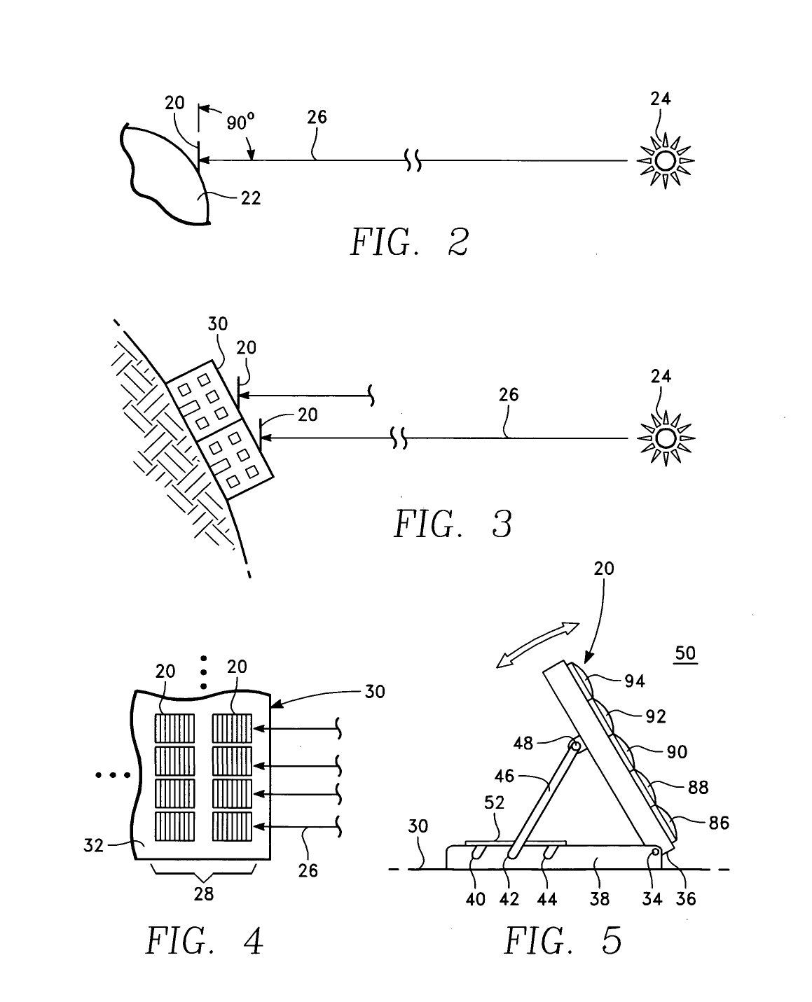

Referring to the drawings more particularly by reference numbers, number 20 in FIGS. 1A and 2 refers to a solar panel constructed according to the present invention in position on the earth 22 with respect to the sun 24. As shown in FIGS. 1A, 1B, and 2, the panel 20 is normally positioned at an angle to the earth 22 approximating the latitude of the panel's location on the earth 22. In most cases, the panel 20 is positioned perpendicular to the sun's rays 26a at mid-morning and mid-afternoon (sun 24a position) so that the sun's rays 26b and 26c strike the lens 27 (the lens 27 extends into the paper) at an acceptance angle of 30° to 35° close to sunrise and sunset (sun position 24b), and at high noon (sun position 24c). However, solar electricity is normally a “topping” electrical source, to supply electricity during peak demands. If the peak demand is caused by air conditioning, ambient air temperature lags the sun 24 by about two hours, so the panel 20 may be orientated to be perpendicular to the rays 26 at up to 2 hours later than mid-morning and mid-afternoon. The total energy converted into electricity, in such instance, will be less, but it will be closer in synchronization to the electrical demand. Note that the sun rays 26a, 26b, and 26c pass through the lens 27 to focus on an arculate path 27′.

FIGS. 3 and 4 show an array 28 of panels 20 as they can be positioned on a roof 30 to maximize the number of panels 20 on the roof's surface 32. The same positioning applies for a solar farm, but the cost of ground area is generally less than on a building's roof 30.

FIG. 5 is a side view of a panel 20 showing one possible adjustable mounting of the panel 20 to a roof 30 or other surface. The panel 20 has a hinge 34 at its lower edge 36 connected to a pair of mounting arms 38 (only one shown). The arms 38 have multiple catches 40, 42, and 44 formed therein which engage with a brace 46 connected to the panel 20 by another hinge 48. The brace 46 can be manually positioned in one of the catches 40, 42, or 44 depending on the season. Catch 40 is used for late spring to early summer, catch 44 is used from late fall to early winter, and catch 42 is used during the remainder of the time. The number of catches 40, 42, and 44 used depends on the value of the electricity produced and the manpower cost to move the panels 20. Generally, in hot climates where the summer days are likely to be cloud free, electricity is more valuable during the summer and a catch may be positioned to maximize the solar energy collected when the sun 24 travels highest in the sky 50. A fixable plate 52 may be positioned over the catches 40, 42, and 44 to retain the brace 46 in the catches 40, 42, or 44 during windy conditions.

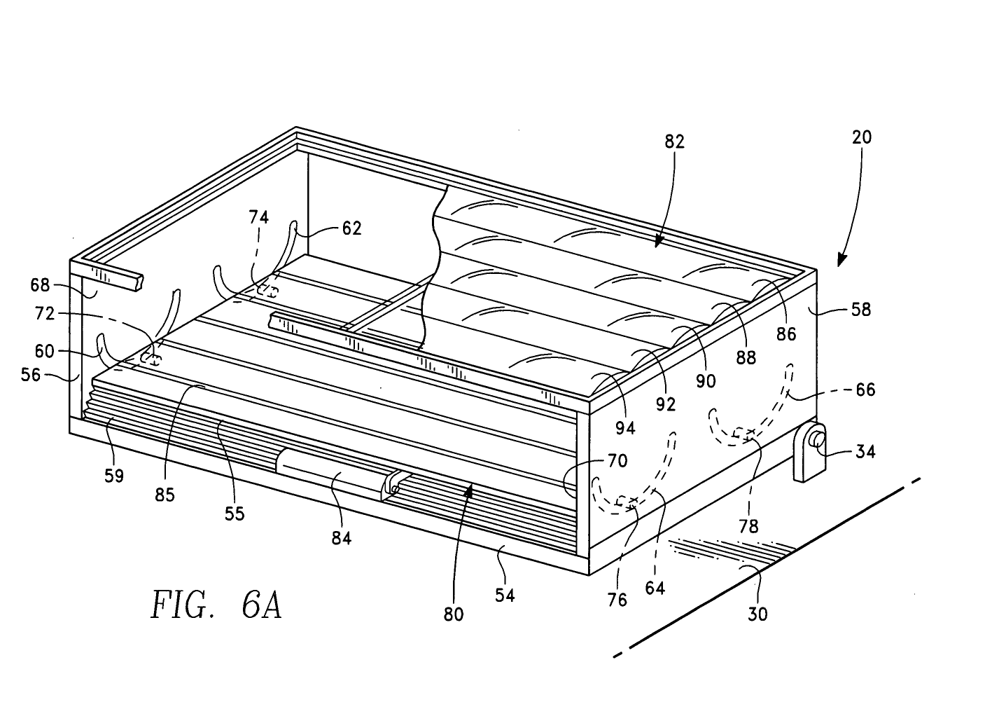

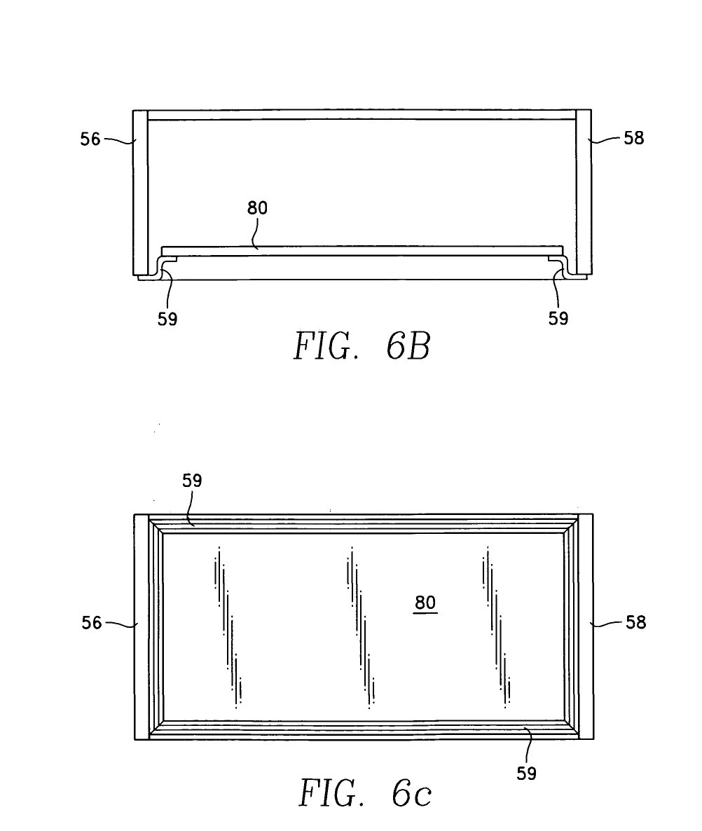

FIG. 6A is a perspective cutaway view of a panel 20 constructed in accordance with the present invention. The panel 20 includes a bottom 54 open to the environment on its back side 55. Upwardly extending from the bottom 54 is an upper side 56 and a lower side 58. As shown in FIGS. 6B and 6C, flexible bellows 59 seal the interior of the panel 20. Each side 56 and 58 have a pair of arculate grooves 60 and 62, and 64 and 66 milled, cut, cast or formed in the interior surfaces 68 and 70 respectively. Pins 72, 74, 76, and 78 fixed to the heat conducting panel 80 extend into the grooves 60, 62, 64, and 66 restricting the movement of the heat conducting panel 80 so that it remains parallel to the lens assembly 82. A combination of springs (not shown) connecting the sides 56 and 58 to the panel 80 may be used to assure the panel remains parallel to the lens assembly 82. Only three of the four grooves 60, 62, 64, or 66 are required to assure that the heat conducting panel 80 remains parallel to the lens assembly 82. To reduce friction and eliminate galling, the pins 72, 74, 76, and 78 may have an exterior ceramic coating and the grooves 60, 62, 64, and 66 may be coated with a low friction material or lubricating material. The heat conducting panel 80 is moved by a suitable controller 84 connected thereto so that the photovoltaic strips 85 thereon are retained in alignment with the concentrated light.

The assembly 82 is an extrusion of five cylindrical linear lens, 86, 88, 90, 92, and 94. The lens 86, 88, 90, 92, and 94 being extruded and of extrudible plastic, are of sufficient optical transmission quality, but must be very economical to manufacture. Higher quality lens arrays may be produced by injection molding, casting, or machining and optical polishing, but their cost, at the present, is high and their usage increases the cost of the panel 20 to a level where little if any money is saved by the present invention in converting solar energy to electricity. As will be explained, the panel 20 is very tolerant of optical aberrations and is a light concentrating system, not an imaging system.

The plastic lenses need be fabricated in high optical clarity material that is resistant to optical and mechanical degradation from environmental exposure of solar radiation, moisture, and weather. A common lens material used is acrylic resin or poly methyl methacrylate (PMMA).

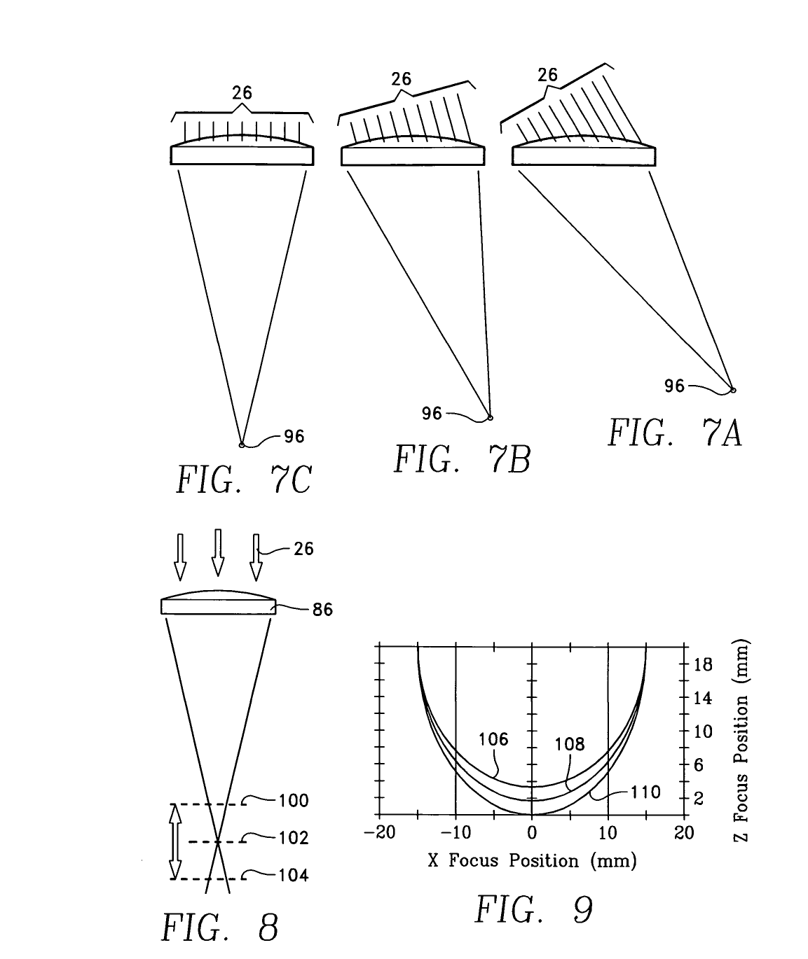

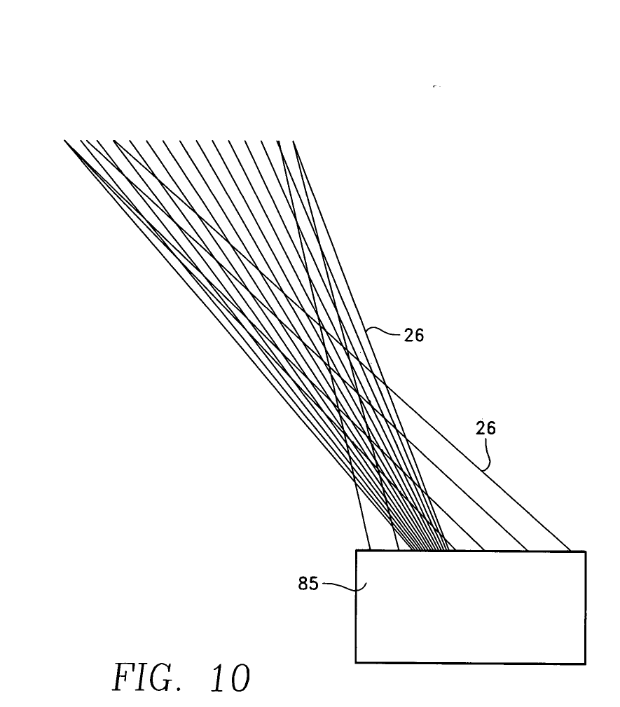

As aforesaid, the panel 20 is oriented with the lens 86, 88, 90, 92, and 94 extending from side 56 to side 58 on the panel 20. The effect of the movement of the sun 24 is shown in FIGS. 7A, 7B, and 7C. Generally the panel 20 starts effective solar energy capture when the sun 24 is about 30° from the lens axis as shown in FIG. 7A. The theoretical convergence 96 of the sun rays 26 moves downwardly and toward the lens axis as shown by FIG. 7B when the sun 24 is 15° from the lens axis, and FIG. 7C when the sun 24 is at 0° from the lens axis. As the sun 24 moves up further across the sky 50, the theoretical convergence 96 moves upwardly and sidewardly, therefore defining the arculate path of the grooves 60, 62, 64, and 66. The term convergence of sun light is used because the system is designed for minimized system cost whereby the lens aperture is maximized for highest solar concentration ratio and least photovoltaic material cost and for widest system sunlight acceptance angle. In these minimized cost solutions optical aberrations are introduced which result in a widening of the effective theoretical concentration zone as illustrated in FIG. 10.

The effective theoretical concentration zone is as illustrated. In these minimized cost solutions optical aberrations are introduced which result in a widening of the concentration zone shown in FIG. 8. The actual convergence may vary as shown in FIG. 8 so the photovoltaic strips are sized to capture a 1 mm strip of light 100 before the focus 102 and a 1 mm strip of light 104 below the focus 102. FIG. 9 is a graph of the upper line of focus 106, the mid-point line of focus 108, and the lower line of focus 110. FIG. 10 is a highly enlarged light ray trace showing aberrations at a 30° sun angle relative to the lens axis after passing through the lens 86 and onto the photovoltaic strip 85.

In a typical lowest cost solar concentrator configuration of this invention has an optical concentration ratio of at least 20 to 1, with lens aperture of 20 mm, a spherical lens array with 22mm radius-of-curvature made by extrusion and embossing roll processing in PMMA plastic, and the photovoltaic cell strip width of 1 mm, and concentrator module depth profile of 5 cm, has the arculate path focal depth alignment tolerances shown in FIG. 9.

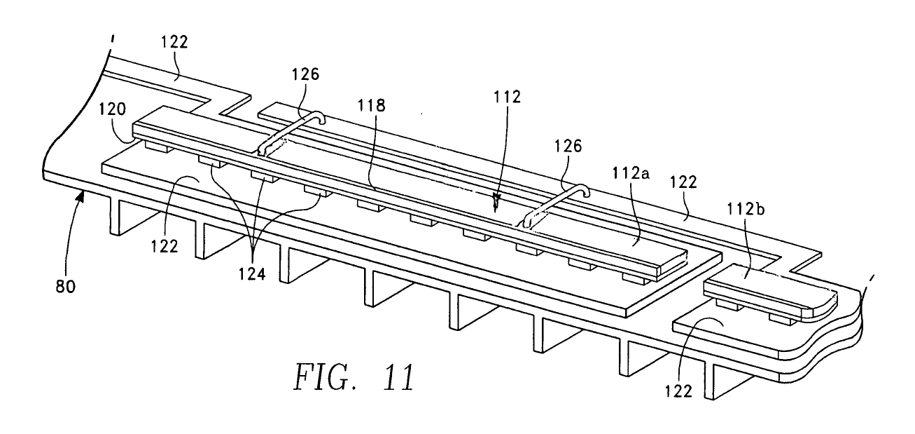

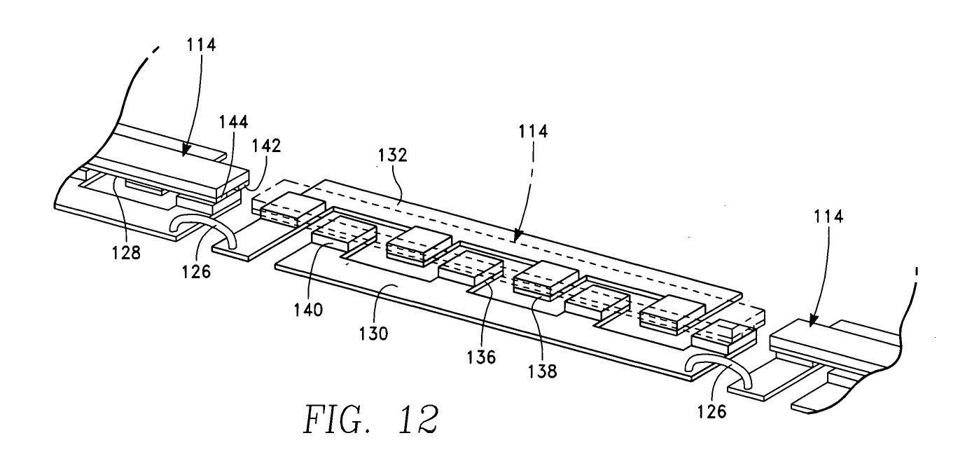

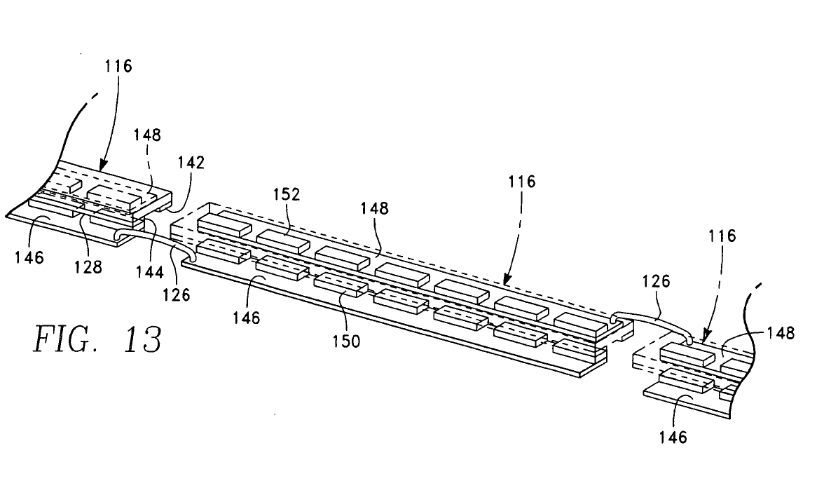

FIGS. 11, 12 and 13 are highly enlarged perspective views of the electrical and thermal connections for three available photovoltaic strips 112, 114, and 116. In FIG.11, strip 112 has a pair of top side electrical terminal traces 118a and 118b and a bottom electrical terminal sheet 120. A heat spreader 122 is electrically and thermally connected to the photovoltaic strip 112 by means of solder or conductive glue dots 124 or by a continuous solder or electrically conductive glue. The strips 112a and 112b are shown connected in series by wires or copper foils 126 extending from heat spreader 122 to the adjacent terminal trace 118. The strips 114 and 116 of FIGS.12 and 13 have both positive and negative terminals (not shown) on the underside 128 thereof. Two heat spreaders 130 and 132 have inwardly extending fingers 136 and 138 respectively with solder or conductive glue dots 140 for attachment with the strips 114. The strips 114 and 116 have bottom traces 142 and 144 which electrically and thermally connect to a pair of parallel heat spreader strips 146 and 148 by means of solder or conductive glue dots 150 and 152. Although the photovoltaic strips 112, 114 or 116 are shown series connected, they also can be series and parallel connected or just parallel connected depending on the voltage and current requirements of a particular insulation.

Heat spreader and electrical bus bar elements 122, 130, 132, 146 and 148 are physically bonded to heat sink 80 by electrically insulating adhesive to provide a direct thermal conduction path to cool the photovoltaic cell strips and to provide a flat mechanical support panel to panel arculate path motion in aligning the plurality of photovoltaic cell strips with the plurality of light concentration lines at all sun positions throughout the day.

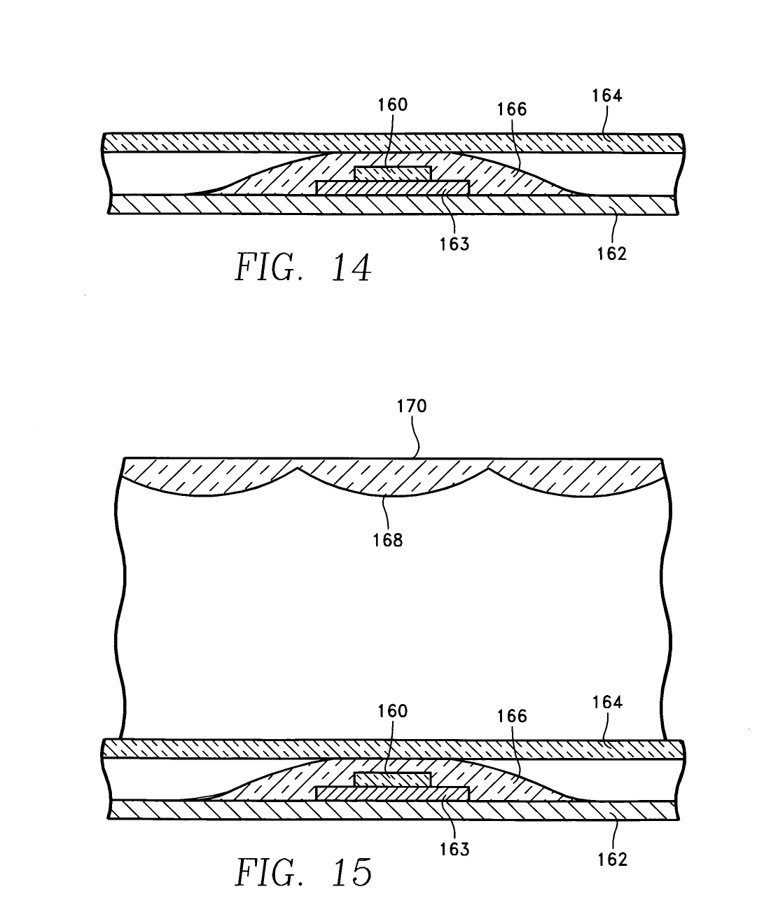

FIG. 14 shows a photovoltaic strip 160 connected to a heat conducting panel 162 with a copper heat spreader and connector 163 and an environmental shield comprising a transparent plastic sheet 164 and index matching transparent glue 166. In FIG. 15, an inverted lens 168 is added to the structure of FIG. 14. The lens 168 can not be as optically desirable as the previously discussed lens, but is advantageous in areas where particulates or oils are in the air, as the flat top surface 170 is easier to clean.

Therefore there has been shown and described novel solar panels and arrays thereof which fulfill all the objects and advantages sought therefore. Many changes, modifications, variations and other uses and applications of the subject invention will, however, become apparent to those skilled in the art after considering this specification and the accompanying drawings. All such changes, modifications, alterations and other uses and applications which do not depart from the spirit and scope of the invention are deemed to be covered by the invention which is limited only by the claims which follow:

1. A device for producing electricity from solar energy, including:
at least one photovoltaic converter to convert solar energy into electrical energy, said photovoltaic converter having:
a converter width; and
a converter length substantially larger than said converter width; and
a transparent solar energy concentrator having:
a concentrator width; and
a concentrator length substantially larger than said concentrator width and being positioned in alignment with said at least one photovoltaic converter whereby solar energy passing through transparent solar energy concentrator is concentrated on said at least one photovoltaic converter, said transparent solar energy concentrator further including:
at least one linear, convex curved, transparent surface for facing the sun through a percentage of the sun's passage across the sky, whereby the solar energy is concentrated while passing through said transparent solar energy concentrator, said at least one photovoltaic converter being mounted for to and from, and lateral movements with respect to said transparent solar energy concentrator so the concentrated solar energy is directed onto said at least one photovoltaic converter during the percentage of the passage of the sun across the sky.

2. The device for producing electricity from solar energy as defined in claim 1 wherein said at least one linear convex curved surface for facing a source of solar energy includes:
a plurality of parallel linear convex curved surfaces oriented parallel to the horizon of the earth and generally being about 60° in arc, whereby the earth's motion causes the solar energy to sweep across said transparent solar energy concentrator during about 60° of the sun's passage across the sky.

3. The device for producing electricity from solar energy as defined in claim 2 wherein said transparent solar energy concentrator is positioned at an angle with respect to the earth generally similar to the latitude of the position of the device on the earth.

4. The device for producing electricity from solar energy as defined in claim 2 wherein said at least one photovoltaic converter includes:
a plurality of photovoltaic cells, each having:
a front surface; and
a back surface, said front surfaces of said plurality of photovoltaic cells being aligned with said plurality of parallel linear convex curved surfaces to convert the solar energy passing there through into electrical energy.

5. The device for producing electricity from solar energy as defined in claim 4 further including:
a heat sink thermally connected to said at least one photovoltaic converter at said back surfaces of said photovoltaic cells.

6. The device for producing electricity from solar energy as defined in claim 5 wherein said photovoltaic cells include:
a first electrical polarity; and
a second electrical polarity, and said heat sink includes:
a first heat spreader conductor electrically conducted to said first electrical polarity of said photovoltaic cells; and
a second heat spreader conductor electrically connected to said second electrical polarity of said photovoltaic cells.

7. The device for producing electricity from solar energy as defined in claim 6 wherein said heat spreader conductor includes:
a plurality of cooling fins there along.

8. The device for producing electricity from solar energy as defined in claim 6 wherein said photovoltaic converter includes:
a front surface facing said solar energy concentrator; and
a transparent environmental shield attached to said front-surface of said photovoltaic converter by index matching transparent glue.

9. The device for producing electricity from solar energy as defined in claim 1 wherein said at least one linear convex curved transparent surface for facing the sun includes:
a plurality of parallel linear convex curved surfaces oriented lengthwise on the earth in a lateral direction, facing toward the sun at about the latitude angle of the location on the earth at which said device is located, whereby the earth's motion causes the solar energy to sweep across said transparent solar energy concentrator.

10. The device for producing electricity from solar energy as defined in claim 9 wherein said at least one photovoltaic converter includes:
a plurality of photovoltaic cells, each having:
a front surface; and
a back surface, said front surfaces of said plurality of photovoltaic cells being aligned with said plurality of parallel linear convex curved surfaces to convert the solar energy passing there through into electrical energy.

11. The device for producing electricity from solar energy as defined in claim 1 wherein said transparent solar energy concentrator includes:
a back flat surface parallel to said at least one photovoltaic element, said at least one photovoltaic converter including:
a first drive control which drives said transparent sheet to and from said transparent solar energy concentrator;
a second drive control which drives said transparent sheet laterally with respect to said transparent solar energy concentrator; and
a controller to control said first and second drive controls to keep the solar energy concentrated by said transparent solar energy concentrator on said at least one photovoltaic element as the sun moves with respect to said device.

12. The device for producing electricity from solar energy as defined in claim 1 further including:
a case, and wherein said at least one photovoltaic converter includes:
at least three sidewardly extending pins, and said case includes at least three arculate grooves in which said pins move to keep said at least one photovoltaic converter in parallel relationship to said transparent solar energy concentrator; and
a drive which moves said at least one photovoltaic converter with said pins in said grooves; and
a controller to control said drive to keep the solar energy concentrated by said transparent solar energy concentrator on said at least one photovoltaic element as the sun moves with respect to said device.

13. A device for producing electricity from solar energy including:
at least one photovoltaic converter to convert solar energy into electrical energy;
a transparent plastic solar energy concentrator including:
at least one front cylindrical surface for facing a source of solar energy; and
a back surface generally parallel to said at least one photovoltaic converter, whereby the solar energy is concentrated while passing through said transparent solar energy concentrator; and
a mechanism for moving said at least one photovoltaic converter in an arculate path with respect to said transparent solar energy concentrator to keep the solar energy falling on said at least one photovoltaic converter for a portion of the sun's transit across the sky.

14. The device for producing electricity from solar energy as defined in claim 13 wherein said mechanism is solar powered.

15. The device for producing electricity from solar energy as defined in claim 13 wherein said at least one cylindrical surface for facing a source of solar energy includes:
a plurality of parallel linear convex curved surfaces oriented parallel to the horizon of the earth and generally being about 60° in arc, whereby the earth's motion causes the solar energy to sweep across said transparent solar energy concentrator during about 60° of the sun's passage across the sky.

16. The device for producing electricity from solar energy as defined in claim 13 wherein said at least one photovoltaic converter includes:
a plurality of photovoltaic cells, each having:
a front surface; and
a back surface, said front surfaces of said plurality of photovoltaic cells being aligned with said plurality parallel convex cylindrical surfaces to convert solar energy passing there through into electrical energy.

17. The device for producing electricity from solar energy as defined in claim 13 further including:
a heat sink having;
a front side; and
a back side, said heat sink front side being thermally connected to said at least one photovoltaic converter at said back surfaces of said photovoltaic cells.

18. The device for producing electricity from solar energy as defined in claim 17 wherein said photovoltaic cells each have:
an electrical output of a first polarity; and
an electrical output of a second opposite polarity, and said heat sink includes:
a heat spreader conductor electrically conducted to said first electrical polarity of said photovoltaic cells.

19. The device for producing electricity from solar energy as defined in claim 17 wherein said heat sink back side includes:
a heat conducting surface.

20. The device for producing electricity from solar energy as defined in claim 13 wherein said at least one front cylindrical surface for facing a source of solar energy includes:
a plurality of parallel convex cylindrical surfaces for orientated lengthwise on the earth in a lateral direction, facing toward the sun at about the latitude angle of the location on the earth at which said device is located, whereby the earth's motion causes solar energy to sweep up and back said transparent solar energy concentrator from morning to afternoon.

21. The device for producing electricity from solar energy as defined in claim 20 wherein said at least one photovoltaic converter includes:
a plurality of photovoltaic cells, each having:
a front surface; and
a back surface, said front surfaces of said plurality of photovoltaic cells being aligned with said plurality of parallel convex cylindrical surfaces to convert the solar energy passing through said plastic solar energy concentrator into electrical energy, said plastic solar energy concentrator being formed by extruding and then embossing to shape.

22. The device for producing electricity from solar energy as defined in claim 13 wherein said transparent plastic solar energy concentrator produces a concentration ratio of over 5 to 1.

23. A low cost device for location as a commercial electricity producer including:
a case;
an array of solar concentrators in fixed positions in said case having a concentration ratio;
a plurality of strips of photovoltaic cells movable with respect to said array of solar concentrators, said array of solar concentrators including:
rows of curved surfaces positioned laterally with respect to the earth; and
an opposite relatively flat surface positioned generally perpendicular to the sun at mid-morning and mid-afternoon at the equinox; and
a movement control to move said plurality of strips of photovoltaic cells in an arculate path and generally parallel to said array of solar concentrators to direct solar energy onto said plurality of strips of photovoltaic cells as the sun moves across the sky.

24. The low cost device for location as a commercial electricity producer as defined in claim 23 wherein said array of solar concentrators have:
an area of collection, said array of solar concentrators, said plurality of strips of photovoltaic cells, and said movement control cost less than an area of said photovoltaic cells having a collection area equal to said area of collection of said array of solar concentrators.

25. The low cost device for location as a commercial electricity producer as defined in claim 23 further including:
a plurality of said cases positioned adjacent to each other in a minimum of space to optimize the electricity produced per unit area.

26. The low cost device for location as a commercial electricity producer as defined in claim 23 further including:
a variable support mechanism to hold said device at at least two positions angled with respect to the earth, whereby the angle of the device may be varied manually with the seasons to increase the solar energy captured by the device.

27. The low cost device for location as a commercial electricity producer as defined in claim 26 wherein said at least two positions include said device being perpendicular to the sun plus up to 15° when the sun rises above the equinox and said device being perpendicular to the sun minus up to 15° when the sun rises only below the equinox.

28. The low cost device for location as a commercial electricity producer as defined in claim 26 wherein said at least two positions are three positions which retain said device generally perpendicular to the sun during the equinox portions of the year, which retain said device generally perpendicular to the sun plus up to 15° during the summer portion of the year, and which retain said device generally perpendicular to the sun minus up to 15° during the winter portion of the year.
